(19) United States
(12) Patent Application Publication
(10) Pub. No.: US 2013/0129945 A1
(43) Pub. Date: May 23, 2013

(54) GLAZING PANEL

(71) Applicants: Anne Durandeau, Paris (FR); Andriy Kharchenko, Palaiseau (FR); Sebastien Roy, Houilles (FR); Hadia Gerardin, Paris (FR); Anne Lorren, Paris (FR)

(72) Inventors: Anne Durandeau, Paris (FR); Andriy Kharchenko, Palaiseau (FR); Sebastien Roy, Houilles (FR); Hadia Gerardin, Paris (FR); Anne Lorren, Paris (FR)

(73) Assignee: SAINT-GOBAIN GLASS FRANCE, Courtbevoie (FR)

(21) Appl. No.: 13/812,694

(22) PCT Filed: Jul. 20, 2011
(86) PCT No.: PCT/FR11/51749

§ 371 Date: Jan. 28, 2013

(30) Foreign Application Priority Data
Jul. 28, 2010 (FR) 1056218

(51) Int. Cl. E06B 3/66; C23C 14/35

(52) U.S. Cl. CPC E06B 3/66; C23C 14/35
USPC 428/34; 428/212; 204/192.29

(57) ABSTRACT

The subject of the invention is a glazing unit comprising a glass substrate (1) equipped on one of its faces, intended to form face 1 of said glazing unit in the use position, with a thin-film multilayer comprising, from the substrate (1), a film (2) of a transparent electrically conductive oxide, an intermediate film (3) having a refractive index lying in the range from 1.40 to 1.55 and having an optical thickness Y, and a photocatalytic film (4) the optical thickness X of which is at most 50 nm, said optical thicknesses X and Y, expressed in nanometers, being such that:

110·e^{-0.025X}≦Y≦135·e^{-0.018X}

The invention relates to the field of glazing units comprising a glass substrate, equipped on at least one of its faces with a thin-film multilayer.

For environmental reasons and reasons related to the need to save energy, dwellings are currently equipped with multiple glazing units, double glazing units and even triple glazing units, often provided with low-E films, intended to limit heat transfer to the exterior of the dwelling. These glazing units, which have a very low thermal transmission coefficient, are however subject to the appearance of water condensation on their external surface, in the form of mist or frost. In the case of a clear sky during the night, radiative heat exchange with the sky cause a temperature drop that is not sufficiently compensated for by heat coming from the interior of the dwelling. When the temperature of the external surface of the glazing unit drops below the dew point, water condenses on said surface, reducing visibility through the glazing unit in the morning, sometimes for a number of hours.

In order to solve this problem, it is known to place a low-E film on face 1 of the glazing unit (the external face), for example a film of a transparent electrically conductive oxide (TCO), so as to reduce radiative exchange with the sky. Application WO 2007/115796 provides, for example, for the use of a multilayer comprising a TCO film, a blocking film and finally a photocatalytic film.

Such a solution, even though it effectively solves most water condensation problems, is not however without its drawbacks. If the thickness of the films is not optimized this solution substantially reduces the G-value of the glazing. The G-value corresponds to the fraction of solar energy transmitted by the glazing into the interior of the dwelling, by direct transmission through the glazing unit and by reemission of radiation absorbed by the glazing unit into the interior. Now, it is important, especially in the winter or in a cold climate, to be able to maximize the transmission of solar heat through the glazing unit, so as to reduce the amount spent on heating.

The object of the invention is to obviate these drawbacks by providing a glazing unit that limits or prevents the appearance of condensation (mist or frost) on the external face, while reducing as little as possible the G-value, and therefore heat transfer into the interior of the dwelling.

Specifically, one subject of the invention is a glazing unit comprising a glass substrate equipped on one of its faces, intended to form face 1 of said glazing unit in the use position, with a thin-film multilayer comprising, from said substrate, a film of a transparent electrically conductive oxide, an intermediate film having a refractive index lying in the range from 1.40 to 1.55 and having an optical thickness Y, and a photocatalytic film the optical thickness X of which is at most 50 nm, said optical thicknesses X and Y, expressed in nanometers, being such that:

110·e^{-0.025X}≦Y≦135·e^{-0.018X}.

The expression “face 1” of the glazing is understood to mean, as is common in the art, the external face of the glazing unit, which face is intended to be positioned in contact with the exterior of the dwelling. The faces of a glazing unit are numbered starting from the exterior, thus face 2 is the face opposite face 1, in other words the other face of the same glass pane. In a multiple glazing unit, comprising two or more glass panes, face 3 is the face of the second glass pane of the glazing unit that faces face 2 and face 4 is the face opposite face 3, etc.

The refractive indices are measured, for example using ellipsometry, at a wavelength of 550 nm. The optical thickness of a film corresponds to the product of the physical thickness (also called the geometrical thickness) of the film and its refractive index.

The glazing unit according to the invention is preferably a multiple glazing unit, especially a double or triple glazing unit, or a higher-multiple glazing unit, for example a quadruple glazing unit. This is because these glazing units have a low thermal transmission coefficient, and are affected more by condensation effects. A double glazing unit is generally formed by two glass panes that face each other and house a gas-filled cavity, for example filled with air, argon or xenon or indeed krypton. Generally, a spacer bar in the form of a metal strip, for example an aluminum strip, is placed on the periphery of the glazing unit, between the glass panes, and securely fastened to the glass panes by an adhesive. The periphery of the glazing unit is sealed using a mastic, for example a silicone, polysulfide or polyurethane mastic, in order to prevent any moisture from entering the gas-filled cavity. In order to limit the ingress of moisture a molecular sieve is often placed in the spacer bar. A triple glazing unit is formed in the same way, though the number of glass panes is now three.

When the glazing unit according to the invention is a triple glazing unit, at least one other face, chosen from faces 2 to 5, is preferably coated with a low-E multilayer. This may in particular be a thin-film multilayer comprising at least one silver film, the or each silver film being placed between dielectric films. The term “low-E” is understood to mean providing an emissivity generally of at most 0.1, especially 0.05. Preferably, two other faces, especially faces 2 and 5 are coated with such a multilayer. Other configurations are also possible, but less preferable: faces 2 and 3, 2 and 4, 3 and 4, 4 and 5, faces 2, 3 and 4, faces 2, 3 and 5, faces 2, 4 and 5 or faces 2, 3, 4 and 5. Other types of multilayer may be placed on the faces of the glazing, for example antireflective multilayers, on face 2, 3, 4, 5 or 6.

When the glazing unit according to the invention is a double glazing unit, face 2 is advantageously coated with a low-E multilayer, especially of the type described above. Alternatively, face 2 may be coated with a solar-control multilayer, though this is not preferred because such a multilayer reduces the G-value.

The glazing unit according to the invention may be employed as any type of glazing unit. It may be incorporated into curtain walling, a roof or a veranda. It may be positioned vertically or at an inclination.

The glass substrate is preferably transparent and colorless (it may then be a clear or extra-clear glass). It may also be tinted, for example blue, green, gray or bronze, though this embodiment, which reduces the G-value, is not preferred. The glass is preferably a soda-lime-silica glass, but it may also be a borosilicate or aluminoborosilicate glass. The thickness of the substrate generally lies in the range from 0.5 mm to 19 mm, preferably from 0.7 to 9 mm, especially from 2 to 8 mm, indeed from 4 to 6 mm. The same applies, if required, to the other glass panes of the multiple glazing unit.

The glass substrate is preferably float glass, i.e. likely to have been obtained via a process that consists in pouring molten glass onto a bath of molten tin (the float bath). In this case, the multilayer may equally well be placed on the “tin” side as on the “atmosphere” side of the substrate. The expressions “atmosphere side” and “tin side” are respectively understood to mean the face of the substrate that was in contact with the atmosphere above the float bath and the face of the substrate that was in contact with the molten tin. The tin side contains a small superficial amount of tin, the tin having diffused into the structure of the glass.

At least one glass pane, including that equipped with the multilayer forming the core of the invention, may be tempered or toughened, so as to increase its strength. As described below, thermal tempering may also be used to improve the emissivity or photocatalytic properties of the films. To improve the acoustic or anti-break-in properties of the glazing unit according to the invention, at least one glass pane of the glazing is possibly laminated to another pane by means of an intermediate sheet made of a polymer such as polyvinyl butyral (PVB) or polyurethane (PU).

The film of a transparent electrically conductive oxide is preferably a film of fluorine-doped tin oxide (SnO₂:F) or a film of mixed indium tin oxide (ITO). Other films are possible, among which thin films based on mixed indium zinc oxides (called IZO), based on zinc oxide gallium-doped or -aluminum-doped, based on niobium-doped titanium oxide, based on zinc or cadmium stannate or based on antimony-doped tin oxide. In the case of aluminum-doped zinc oxide, the doping level (i.e. the weight of aluminum oxide relative to the total weight) is preferably lower than 3%. In the case of gallium, the doping level may be higher, typically lying in the range from 5 to 6%. In the case of ITO, the atomic percentage of Sn preferably lies in the range from 5 to 70%, especially from 10 to 60%. For films based on fluorine-doped tin oxide, the atomic percentage of fluorine is preferably at most 5%, generally from 1 to 2%.

These films have a good weatherability, necessary when the multilayer is placed on face 1 of the glazing, which is not the case for other low-E films such as silver films. The latter must necessarily be located on an internal face of the multiple glazing unit.

ITO is particularly preferred, especially relative to SnO₂:F. Since ITO has a higher electrical conductivity, its thickness may be smaller for the same emissivity level, thereby minimizing the reduction in G-value. Easily deposited by sputtering, especially magnetron sputtering, these films have lower roughness and therefore are less prone to fouling. Specifically, during manufacture, handling and maintenance of the glazing units, rougher films have a tendency to trap various residues that are particularly difficult to remove.

On the other hand, one of the advantages of fluorine-doped tin oxide is that it may be easily deposited by chemical vapor deposition (CVD) which, in contrast to sputtering, does not require a subsequent heat treatment and may be implemented on the line producing flat glass using the float process.

The thickness of the TCO film is adjusted depending on the nature of the film, so as to obtain the desired emissivity, which depends on the anti-condensation performance sought. The emissivity of the TCO film is preferably lower than or equal to 0.4, especially 0.3. For ITO films, the geometrical thickness will generally be at least 40 nm, even 50 nm and even 70 nm, and often 150 nm or 200 nm at most. For fluorine-doped tin oxide films, the geometrical thickness will generally be at least 120 nm, even 200 nm and often 500 nm at most.

When the glazing is intended to be placed in the vertical position, the emissivity is preferably at most 0.4, indeed 0.3. In the case of fluorine-doped tin oxide, this generally requires geometrical thicknesses of at least 120 nm, indeed 200 nm. In the case of ITO, the geometrical thickness will generally be at least 40 nm, even 50 nm, often 150 nm at most.

When the glazing is intended to be placed at an inclination, for example in roofing applications, the emissivity is preferably at most 0.3, indeed 0.2 and even 0.18. The geometrical thicknesses of the fluorine-doped tin oxide will preferably be at least 300 nm and those of ITO at least 60 nm, indeed 70 nm or 100 nm and often 200 nm at most.

The term “emissivity” is understood to mean the normal emissivity at 283 K in the sense of standard EN 12898.

The refractive index of the transparent electrically conductive oxide film preferably lies in the range from 1.7 to 2.5.

In order to optimize the effect of the invention, the refractive index of the intermediate film is preferably at most 1.50, indeed 1.48.

The intermediate film is advantageously based on silica, even made of silica. It will be understood that the silica may be doped, or nonstoichiometric. By way of example, the silica may be doped with aluminum or boron atoms, so as to make sputtering it easier. In the case of chemical vapor deposition (CVD), the silica may be doped with phosphorus or boron atoms, thereby accelerating deposition. The silica may also be doped with nitrogen or carbon atoms in sufficiently small amounts that the refractive index of the film remains in the aforementioned ranges. Such an intermediate film also has the advantage of protecting the TCO film, endowing it with better weatherability and an improved tempering withstand. In the case of a TCO based on fluorine-doped tin oxide, the intermediate film furthermore has the advantage of smoothing the surface, reducing the abrasiveness of the film.

The photocatalytic film is preferably based on titanium oxide, especially being a film of titanium oxide, the refractive index of which in particular lies in the range from 2.0 to 2.5. The titanium oxide is preferably at least partially crystallized in the anatase form, which is the most active phase from the point of view of photocatalysis. Mixtures of the anatase phase and the rutile phase have also been observed to be very active. The titanium dioxide may optionally be doped with a metal ion, for example a transition-metal ion, or with atoms of nitrogen, carbon or fluorine, etc. The titanium dioxide may also be substoichiometric or superstoichiometric. Although titanium oxide is clearly preferred, other photocatalytic oxides may also be employed, among which SrTiO₃, ZnO, SiC, GaP, CdS, CdSe, MoS₃, SnO₂, ZnO, WO₃, Fe₂O₃, Bi₂O₃, Nb₂O₅, KTaO₃, BiVO₄, Bi₂WO₆.

In the glazing unit according to the invention, the entire surface of the photocatalytic film, especially a titanium-oxide-based film, preferably makes contact with the exterior, so as to be able to fully exercise its self-cleaning function. It may however be advantageous to coat the photocatalytic film, especially a film of titanium dioxide, with a thin hydrophilic film, especially based on silica, so as to improve the durability of the hydrophilicity.

The optical thickness X of the photocatalytic film, especially a titanium-oxide-based film, is preferably at most 40 nm, especially 30 nm. Its geometrical thickness is advantageously at most 20 nm, indeed even 15 nm, or else 10 nm, and is preferably greater than or equal to 5 nm. Very thin films, although less active photocatalytically speaking, have however good self-cleaning, antifouling and antimisting properties. Even for films with a very small thickness, the photocatalytic titanium oxide has the particularity when it is irradiated with solar light of becoming extremely hydrophilic, with water contact angles smaller than 5° and even 1°, thereby allowing water to run off more easily, removing dirt deposited on the surface of the film. Furthermore, thicker films reflect more light, reducing the G-value.

According to one possible embodiment, no film is placed between the transparent electrically conductive film and the intermediate film, and/or between the intermediate film and the photocatalytic film. Alternatively, a protective film may be placed between the TCO film, especially when it is made of ITO, and the intermediate film. This film, the thickness of which is advantageously at most 10 nm, especially 5 nm, indeed even 2 nm, makes it possible to protect the TCO, in particular the ITO, during the deposition of the intermediate film, especially when the film is deposited by sputtering, and during optional subsequent heat treatments. The refractive index of the protective film is preferably higher than or equal to that of the TCO film. Silicon nitride is in particular preferred.

It is also possible to place a neutralizing film, or a neutralizing multilayer of films, between the substrate and the film of a transparent electrically conductive oxide. In the case of a single film, its refractive index preferably lies between the refractive index of the substrate and the refractive index of said film of a transparent electrically conductive oxide. Such films or film multilayers make it possible to influence the reflective appearance of the glazing unit, especially its color in reflection. Bluish colors, characterized by negative b* color coordinates, are preferred. By way of nonlimiting example, it is possible to use a film of mixed silicon and tin oxide (SiSnOₓ), of silicon oxycarbide or oxynitride, of aluminum oxide or of mixed titanium and silicon oxide. A film multilayer comprising two films of high and low index, for example a TiO₂/SiO₂, Si₃N₄/SiO₂ or TCO/SiO₂ multilayer may also be used (in the latter case, the TCO may be the same as the one used before in the multilayer, or another TCO). The geometrical thickness of this or these films preferably lies in the range from 15 to 70 nm. When the film of a transparent electrically conductive oxide is a fluorine-doped tin oxide, the neutralizing sublayer is preferably made of silicon oxycarbide or of mixed silicon and tin oxide. When the film of a transparent electrically conductive oxide is made of ITO, a neutralizing film made of silicon oxynitride or an Si₃N₄/SiO₂ multilayer is preferably placed beneath this film.

In particular, when the film of a transparent electrically conductive oxide is a film of ITO, an adhesive film is preferably placed between the substrate and the neutralizing film or neutralizing multilayer. This adhesive film, which advantageously has a refractive index near that of the glass substrate, enables improved retention under tempering conditions because it promotes bonding of the neutralizing film. The adhesive film is preferably made of silica. Its geometrical thickness preferably lies in the range from 20 to 200 nm, especially from 30 to 150 nm.

The various preferred embodiments described above may of course be combined with one another. All possible combinations are of course not explicitly described in the present text. A few examples of particularly preferred multilayers are given below:

1. glass/SiOC/SnO₂: F/SiO₂/TiO₂

2. glass/SiSnOₓ/SnO₂:F/SiO₂/TiO₂

3. glass/(SiO₂)/SiOₓN_{y}/ITO/Si₃N₄/SiO₂/TiO₂

4. glass/SiO₂/Si₃N₄/SiO₂/ITO/Si₃N₄/SiO₂/TiO₂

5. glass/Si₃N₄/SiO₂/ITO/Si₃N₄/SiO₂/TiO₂.

In these multilayers, the geometrical thickness of the TiO₂ film is advantageously at most 15 nm, even 10 nm. The thickness of the TCO film is independently chosen, depending on the required emissivity, as explained hereinabove.

Multilayers 1 and 2 use a TCO film made of fluorine-doped tin oxide. These multilayers are preferably obtained by chemical vapor deposition, generally directly, on the float-glass line.

Multilayers 3 to 5, which use ITO, are preferably obtained by magnetron sputtering. Examples 3 and 4 contain, on the glass, an adhesive film made of silica (optionally, for example 3), then a neutralizing film made of silicon oxynitride or a neutralizing multilayer consisting of a film of silicon nitride surmounted by a silica film, the TCO film, a protective film made of silicon nitride, an intermediate silica film and finally the photocatalytic film made of titanium dioxide. Example 5 corresponds to example 4, but without the adhesive silica film. The given formulae do not indicate the real stoichiometry of the films or any eventual doping.

The glazing unit according to the invention is preferably obtained by a method comprising a plurality of steps. The multilayer films are deposited on the glass substrate, which generally takes the form of a large glass pane measuring 3.2×6 m², or directly on the ribbon of glass during or just after the float process, and then the substrate is cut to the final size of the glazing unit. After the edges have been finished the multiple glazing unit is then manufactured by associating the substrate with other glass panes, themselves optionally equipped beforehand with functional coatings, for example low-E coatings.

The various films of the multilayer may be deposited on the glass substrate by any thin-film deposition process. It may for example be a sol-gel process, (liquid or solid) pyrolysis, chemical vapor deposition (CVD), especially plasma-enhanced chemical vapor deposition (PECVD), optionally at atmospheric pressure (AP-PECVD), or evaporation.

According to one preferred embodiment, the films of the multilayer are obtained by chemical vapor deposition, directly on the production line of the float-glass pane. This is preferably the case when the film of TCO is a film of fluorine-doped tin oxide. The film is sputtered from precursors through nozzles, onto the hot glass ribbon. The various films may be deposited at various points on the line: in the float chamber, between the float chamber and the lehr or in the lehr. The precursors are generally organometallic molecules or molecules of the halide type. By way of example, mention may be made, for fluorine-doped tin oxide, of tin tetrachloride, monobutyltin trichloride (MBTCL), trifluoroacetic acid or hydrofluoric acid. Silicon oxide may be obtained using silane, tetraethoxysilane (TEOS) or indeed hexamethyldisiloxane (HMDSO), optionally using an accelerator such as triethylphosphate. Titanium oxide may be obtained from titanium tetrachloride or from titanium isopropoxide. The CVD process, comprising deposition onto hot glass, has the advantage of directly producing a well crystallized TCO film and a well-crystallized photocatalytic film.

According to another preferred embodiment, the films of the multilayer are obtained by sputtering, especially magnetron sputtering. This is preferably the case when the TCO film is an ITO film. In this process, a plasma is created under a high vacuum near a target comprising the chemical elements to be deposited. The active species of the plasma bombard the target and tear off said elements which are deposited on the substrate forming the desired thin film. This process is said to be “reactive” when the film consists of a material resulting from a chemical reaction between the elements torn off from the target and the gas contained in the plasma. The main advantage of this process is that it is possible to deposit a very complicated multilayer of films on a given line by running the substrate under various targets in succession, this generally occurring in one and the same device.

However, the magnetron process has a drawback when the substrate is not heated during the deposition: the TCO and titanium oxide films obtained are poorly crystallized such that their respective emissivity and photocatalytic activity properties are not optimized. A heat treatment is then necessary.

This heat treatment, intended to increase the crystallization of the TCO and photocatalytic films, is preferably chosen from tempering, annealing or rapid-annealing treatments. The improvement in the crystallization may be quantified by the increase in the degree of crystallization (i.e. the proportion of crystalline material by weight or by volume) and/or the size of the crystalline grains (or the size of the coherent diffraction domains measured by X-ray diffraction methods or by Raman spectroscopy). This increase in crystallization may also be verified indirectly, by way of the improvement in the properties of the film. In the case of a TCO film, the emissivity decreases, preferably by at least 5% in relative magnitude, even at least 10% or 15%, and likewise for its light and energy absorption. In the case of titanium dioxide films, the increase in crystallization leads to an increase in photocatalytic activity. The activity is generally measured by following the degradation of model pollutants, such as stearic acid or methylene blue.

The tempering or annealing treatment is generally carried out in a furnace, a tempering furnace or an annealing furnace, respectively. The entire substrate is raised to a high temperature, to at least 300° C. in the case of an anneal, and to at least 500° C., even 600° C., in the case of a temper.

The rapid annealing is preferably implemented using a flame, a plasma torch or a laser. In this type of process a relative motion is created between the substrate and the device (flame, laser, plasma torch). Generally, the device is moveable, and the coated substrate runs past the device so that its surface may be treated. These processes deliver a high energy density to the coating to be treated in a very short space of time, thus limiting diffusion of the heat into the substrate and therefore heating of said substrate. The temperature of the substrate is generally at most 100° C., indeed 50° C. and even 30° C. during the treatment. Each point of the thin film is subjected to the rapid-annealing treatment for an amount of time generally smaller than or equal to 1 second, indeed 0.5 seconds.

The rapid-annealing heat treatment is preferably implemented using a laser emitting in the infrared or visible. The wavelength of the laser radiation preferably lies in the range from 530 to 1200 nm, or from 600 to 1000 nm, especially from 700 to 1000 nm, indeed from 800 to 1000 nm. Preferably laser diodes are used, for example emitting at a wavelength of about 808 nm, 880 nm, 915 nm or indeed 940 nm or 980 nm. Systems of diodes make it possible to obtain very high powers, enabling surface power densities at the coating to be treated of higher than 20 kW/cm², even 30 kW/cm² to be obtained.

The laser radiation is preferably emitted in at least one laser beam that forms a line (called a “laser line” in the rest of the text) which simultaneously irradiates all or some of the width of the substrate. This embodiment is preferred because it avoids the use of expensive movement systems which are generally bulky and difficult to maintain. The in-line laser beam may especially be obtained using systems of high-power laser diodes combined with focusing optics. The thickness of the line preferably lies between 0.01 and 1 mm. The length of the line typically lies between 5 mm and 1 m; the profile of the line may especially be a Gaussian or tophat profile. The laser line that simultaneously irradiates all or some of the width of the substrate may consist of a single line (then irradiating the entire width of the substrate), or of a plurality of optionally separate lines. When a plurality of lines is used, it is preferable for them to be placed so that the entire area of the multilayer is treated. The or each line is preferably placed at right angles to the run direction of the substrate, or placed obliquely. The various lines may treat the substrate simultaneously, or in a delayed manner. The important point is that the entire area to be treated is treated. The substrate may thus be moved, especially so as to run translationally past the stationary laser line, generally below but optionally above the laser line. This embodiment is particularly advantageous for a continuous treatment. Alternatively, the substrate may be stationary and the laser may be moved. Preferably, the difference between the respective speeds of the substrate and the laser is greater than or equal to 1 meter per minute, or 4 meters per minute or even 6, 8, 10 or 15 meters per minute, so as to ensure a high treatment rate. When it is the substrate that is moving, especially translationally, it may be moved using any mechanical conveying means, for example belts, rollers or trays running translationally. The conveying system is used to control and regulate the run speed. The laser may also be moved so as to adjust its distance from the substrate, which may in particular be useful when the substrate is bent, but not only in such a case. Indeed, it is preferable for the laser beam to be focused onto the coating to be treated so that the latter is located at a distance of less than or equal to 1 mm from the focal plane. If the system for moving the substrate or moving the laser is not sufficiently precise as regards the distance between the substrate and the focal plane, it is preferable to be able to adjust the distance between the laser and the substrate. This adjustment may be automatic, especially regulated using a distance measurement upstream of the treatment.

The laser radiation device may be integrated into a film deposition line, for example a magnetron sputtering line, or a chemical vapor deposition (CVD) line, especially a plasma-enhanced chemical vapor deposition (PECVD) line, whether under vacuum or at atmospheric pressure (AP-PECVD).

Another subject of the invention is the use of the glazing unit according to the invention to reduce the appearance of condensated water (especially mist or frost) on the surface of said glazing unit.

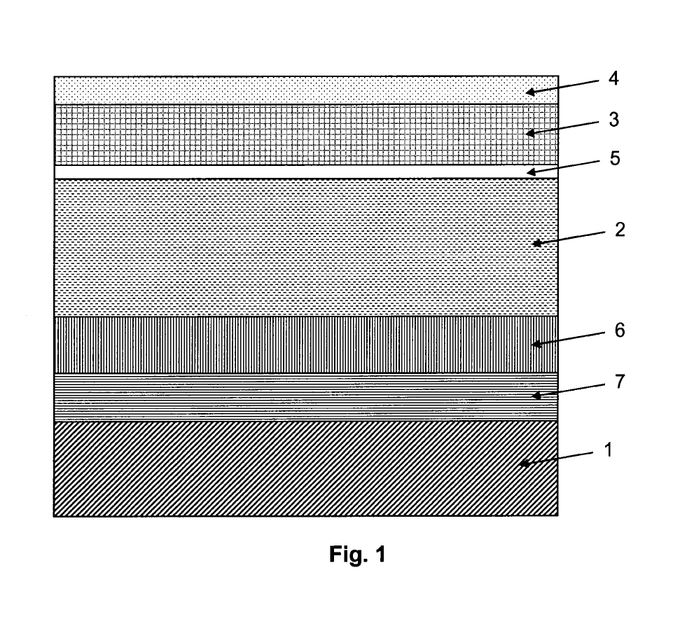

FIG. 1 illustrates schematically a cross section through part of the glazing unit according to the invention. Only the multilayer placed on face 1 of the glazing unit and a part of the glass substrate are shown.

Shown, deposited on the substrate 1 (typically made of glass) are: the film 2 of a transparent electrically conductive oxide (typically ITO), the intermediate film 3 (typically made of SiO₂) and the photocatalytic film 4 (typically made of TiO₂). The optional films are the protective film 5 (typically made of Si₃N₄), the neutralizing film or neutralizing multilayer 6 (typically an Si₃N₄/SiO₂ multilayer) and the adhesive film 7 (for example made of SiO₂).

The following examples illustrate the invention without however limiting it.

### EXAMPLE 1

This example illustrates an embodiment in which the films were deposited by CVD (chemical vapor deposition), the TCO being fluorine-doped tin oxide (SnO₂: F).

Multilayers were deposited in a known way on a glass substrate, these multilayers consisted, starting from the substrate, of a neutralizing film of silicon oxycarbide (of generic formula SiOC) having a refractive index of 1.65, a TCO film made of fluorine-doped tin oxide having a refractive index of 1.8, an intermediate silica film having a refractive index of 1.48 and finally a photocatalytic film made of TiO₂ having a refractive index of 2.0. As in all the text, the refractive indices are given for a wavelength of 550 nm.

The substrate employed in the context of the example was a pane of clear glass, 4 mm in thickness, sold under the trade name SGG Planilux® by the applicant.

Table 1 below shows, for each sample, whether a sample according to the invention or a comparative sample:
the geometrical thicknesses (in nm) of each of the films of the multilayer;
the energy transmission of the multilayer-coated substrate (or direct solar-energy transmission factor), denoted TE, in the sense of standard EN 410:1998; and
the color coordinates a*, b* in reflection from the multilayer side, calculated under illuminant D65 as reference and with a CIE (1931) reference observer.

TABLE 1

| | C1 | C2 | 1 | 2 |
|---|---|---|---|---|
| TiO₂ (nm) | 15 | 15 | 15 | 15 |
| SiO₂ (nm) | 20 | 80 | 50 | 50 |
| SnO₂:F (nm) | 300 | 300 | 300 | 300 |
| SiOC (nm) | 45 | 45 | 45 | 0 |
| TE (%) | 71.5 | 71.9 | 72.8 | 72.5 |
| a* | | | −0.5 | −11.2 |
| b* | | | −0.9 | 4.4 |

Comparative examples C1 and C2 had an intermediate film the thickness of which was not optimized, in contrast to examples 1 and 2 according to the invention.

This led, in the examples according to the invention, to an increase in the energy transmission of more than 0.5%, indeed 1%.

Comparison between examples 1 and 2 illustrated the effect of the neutralizing SiOC film: the multilayer of example 2, which did not have this film, had a less neutral appearance in reflection, having a yellow-green tinge.

A triple glazing unit was produced using substrates C1, C2 and 1. The photocatalytic multilayer was placed on face 1 of the glazing unit, whereas two low-E multilayers based on silver were placed on face 2 and 5, respectively.

Table 2 below shows in each case:
the energy transmission of the glazing (or direct solar-energy transmission factor), denoted TE; and
the G-value of the glazing, denoted g.

These two quantities were calculated according to standard EN 410:1998.

TABLE 2

| | C1 | C2 | 1 |
|---|---|---|---|
| TE (%) | 44.9 | 45.3 | 45.8 |
| g (%) | 52.1 | 52.5 | 53.1 |

The choice of the thickness of the intermediate film therefore makes it possible to obtain a very substantial increase in the G-value.

### EXAMPLE 2

This example illustrates an embodiment in which the films were deposited by magnetron sputtering, the TCO being ITO (mixed tin and indium oxide).

Multilayers were deposited in a known way on a glass substrate, these multilayers consisted, starting from the substrate, of a neutralizing multilayer formed from a film of silicon nitride (Si₃N₄) having a refractive index equal to 2.0, then a silica film having a refractive index equal to 1.48, a TCO film made of mixed tin and indium oxide (ITO) having a refractive index of 1.8, an intermediate film made of silica (SiO₂) having a refractive index of 1.48 and finally a photocatalytic film of TiO₂, the refractive index of which was 2.5. The multilayer-coated substrate was subjected to an annealing step after the films had been deposited. The substrate was the same as that used in the preceding examples.

Table 3 below shows, for each sample, according to the invention or for the purposes of comparison:
the geometrical thicknesses (in nm) of each of the films of the multilayer;
the energy transmission (or direct solar-energy transmission factor), denoted TE, in the sense of standard EN 410:1998, of the multilayer-coated substrate; and
the color coordinates a*, b* in reflection from the multilayer side, calculated under illuminant D65 as reference and using the CIE (1931) reference observer.

TABLE 3

| | C3 | C4 | 3 | 4 |
|---|---|---|---|---|
| TiO₂ (nm) | 12 | 12 | 12 | 12 |
| SiO₂ (nm) | 10 | 70 | 40 | 40 |
| ITO (nm) | 100 | 100 | 100 | 100 |
| SiO₂ (nm) | 11 | 11 | 11 | 0 |
| Si₃N₄ (nm) | 16.5 | 16.5 | 16.5 | 0 |
| TE (%) | 76.3 | 76.2 | 77.9 | 77.4 |
| a* | | | −4.4 | 10.6 |
| b* | | | −9.6 | −20.6 |

Comparative examples C3 and C4 had an intermediate film the thickness of which was not optimized, in contrast to examples 3 and 4 according to the invention.

This led, for the examples according to the invention, to an increase in the energy transmission of at least 1%.

Comparison between examples 3 and 4 illustrated the effect of the neutralizing Si₃N₄/SiO₂ multilayer: the multilayer of example 4, which did not have this film, had a less neutral appearance in reflection, having a violet tinge.

A triple glazing unit was produced using substrates C3, C4 and 3. The photocatalytic multilayer was placed on face 1 of the glazing unit, whereas two low-E multilayers based on silver were placed on face 2 and 5, respectively.

Table 4 below shows in each case:
the energy transmission of the glazing (or direct solar-energy transmission factor), denoted TE; and
the G-value of the glazing, denoted g.

These two quantities were calculated according to standard EN 410:1998.

TABLE 4

| | C3 | C4 | 3 |
|---|---|---|---|
| TE (%) | 47.3 | 47.2 | 48.2 |
| g (%) | 56.0 | 55.8 | 57.0 |

The choice of the thickness of the intermediate film according to the invention therefore makes it possible to obtain a very substantial increase in the G-value, of at least 1% in absolute terms. The use of ITO furthermore makes it possible to increase the G-value, relative to fluorine-doped tin oxide, for a comparable emissivity level (and therefore anticondensation effect).

A very thin protective film made of silicon nitride may be placed between the TCO film and the intermediate film, without substantially changing the optical and energy properties of the glazing unit.

The various glazing units given in the examples greatly reduce the appearance of water condensation such as mist or frost.

1. A glazing unit, comprising:
a glass substrate comprising, on an external face thereof, a thin-film multilayer comprising, from the substrate:
a film comprising a transparent electrically conductive oxide;
an intermediate film having a refractive index in the range from 1.40 to 1.55 and an optical thickness, Y; and
a photocatalytic film having an optical thickness, X, of which is at most 50 nm,
wherein the optical thicknesses X and Y, expressed in nanometers, satisfy the relation:
110·e^{-0.025X}≦Y≦135·e^{-0.018X}.

2. The glazing unit of claim 1, which is a multiple glazing unit.

3. The glazing unit of claim 1, wherein the film comprising the transparent electrically conductive oxide is a film comprising a fluorine-doped tin oxide or a film comprising mixed indium tin oxide.

4. The glazing unit of claim 1, wherein the refractive index of the film comprising the transparent electrically conductive oxide is in the range from 1.7 to 2.5.

5. The glazing unit of claim 1, wherein the film comprising the transparent electrically conductive oxide has an emissivity less than or equal to 0.4.

6. The glazing unit of claim 1, wherein the intermediate film comprises silica.

7. The glazing unit of claim 1, wherein the photocatalytic film comprises titanium oxide.

8. The glazing unit of claim 7, wherein the photocatalytic film is a titanium oxide film having a refractive index in the range from 2.0 to 2.5.

9. The glazing unit of claim 1, wherein the optical thickness X is at most 40 nm.

10. The glazing unit of claim 1, wherein the thin-film multilayer further comprises a protective film between the film comprising the transparent electrically conductive oxide, especially a mixed indium tin oxide, and the intermediate film.

11. The glazing unit of claim 1, further comprising a neutralizing film or a neutralizing multilayer of films between the substrate and the film comprising the transparent electrically conductive oxide.

12. The glazing unit of claim 11, wherein the film comprising the transparent electrically conductive oxide is a mixed indium tin oxide film, and the glazing unit further comprises an adhesive film between the substrate and the neutralizing film or neutralizing multilayer.

13. The glazing unit of claim 1, wherein the multilayer positioned on the external face of the substrate is selected from the following multilayers:
glass/SiOC/SnO₂:F/SiO₂/TiO₂;
glass/SiSnOₓ/SnO₂:F/SiO₂/TiO₂;
glass/SiO₂/SiOₓN_{y}/ITO/Si₃N₄/SiO₂/TiO₂;
glass/SiO₂/Si₃N₄/SiO₂/ITO/Si₃N₄/SiO₂/TiO₂; and
glass/Si₃N₄/SiO₂/ITO/Si₃N₄/SiO₂/TiO₂.

14. The glazing unit of claim 1, which is a triple glazing unit comprising three panes, wherein a first face of the first pane is the external face comprising the thin-film multilayer and wherein a further face of the panes comprises a multilayer having low-E properties,
wherein the further face is: a second face of the first pane, which is opposite to the first face of the first pane; a first face of the second pane facing the first pane; a second face of the second pane, which is opposite to the first face of the second pane; a first face of the third pane facing the first and second panes; or any mixture thereof.

15. A method for producing the glazing unit of claim 1, the method comprising:
sputtering the films of the thin-film multilayer; and then
heat treating the thin-film multilayer to improve the crystallization of the TCO film and the photocatalytic film, wherein the heat treatment comprises tempering, annealing, or rapid-annealing.

16. The method of claim 15, wherein the rapid annealing is implemented with a flame, a plasma torch, or a laser.

17. The glazing unit of claim 1, which is configured to reduce the appearance of condensated water on the surface of the glazing unit.

18. The glazing unit of claim 1, wherein the film comprising the transparent electrically conductive oxide has an emissivity less than or equal to 0.3.

19. The glazing unit of claim 1, wherein the optical thickness X is at most 30 nm.

20. The glazing unit of claim 10, wherein the film comprising the transparent electrically conductive oxide is a mixed indium tin oxide film.
